(19) United States
(12) Patent Application Publication
(10) Pub. No.: US 2025/0164426 A1
(43) Pub. Date: May 22, 2025

(54) COMPENSATED CONDUCTIVITY DETERMINATION

(71) Applicant: Endress+Hauser SE+Co. KG, Maulburg (DE)

(72) Inventors: Armin Wernet, Rheinfelden (DE); Kaj Uppenkamp, Wehr (DE)

(21) Appl. No.: 18/840,241

(22) PCT Filed: Feb. 13, 2023
(86) PCT No.: PCT/EP2023/053531

§ 371 Date: Aug. 21, 2024

(30) Foreign Application Priority Data
Feb. 23, 2022 (DE) 10 2022 104 312.6

(51) Int. Cl. G01N 27/04; G01F 23/24; G01F 23/26; G01N 27/07; G01N 27/22

(52) U.S. Cl. CPC G01N 27/045; G01F 23/24; G01F 23/26; G01N 27/07; G01N 27/226; G01N 27/228

(57) ABSTRACT

A method for determining and/or monitoring the conductivity of a medium using a measuring probe having at least one electrode comprises method steps as follows: supplying the measuring probe with an excitation signal, receiving a received signal by the measuring probe, ascertaining an ohmic part of the received signal, and determining the conductivity of the medium based on the ohmic part of the received signal. Furthermore, the invention relates to a device embodied for performing the method of the invention.

The invention relates to a method for determining the conductivity of a medium by means of a measuring probe having at least a first electrode. The medium is located in a containment, which can be, for example, a container or a pipeline. The invention relates further to a device embodied for performing the method of the invention.

The electrical conductivity of a medium can be ascertained, for example, by means of a conductivity measuring cell, such as described, for example, in EP0990894A2, or by means of an inductive sensor.

However, also suited for determining the conductivity of a medium are field devices based on the capacitive and/or conductive measuring principles. These are frequently used also for determining and/or monitoring a fill level or limit level. Such capacitive and/or conductive measuring devices have typically an essentially cylindrical measuring probe having at least one electrode introduced, at least partially, into a containment. On the one hand, especially, for continuous fill level measurement, rod shaped measuring probes extending vertically into the container are widely used. Known for detecting a limit level, however, are also measuring probes introducible into the side wall of a container and, especially, also such, which mount essentially flushly with the container wall.

During measurement operation, the measuring probe, especially a transmitting electrode of the measuring probe, is supplied with an excitation signal, as a rule, in the form of an alternating current signal. From the response signal received by the measuring probe, then the process variable of interest can be determined. In the case of the capacitive measuring principle, the dependence of the response signal on the capacitance of a capacitor formed by a first electrode of the measuring probe and the wall of the container or an additional electrode of the measuring probe is taken into consideration, in order to ascertain the desired process variable. Depending on conductivity of the medium, either the medium or an insulation of the measuring probe can form the dielectric of the capacitor.

For evaluating the response signal received by the measuring probe, frequently an apparent electrical current measurement or an admittance measurement is performed. In the case of an apparent electrical current measurement, the magnitude of the apparent electrical current flowing through the sensor unit is measured. The apparent electrical current includes, however, an active- and a reactive part. Therefore, in the case of an admittance measurement, besides the apparent electrical current, the phase angle between the apparent electrical current and the voltage applied to the measuring probe is measured. The additional determining of the phase angle enables, moreover, obtaining information concerning possible accretion formation, such as is known, for example, from DE102004008125A1.

In the case of the conductive measuring principle, in contrast, it is detected, whether a conductive medium creates an electrical contact between one of the electrodes and the wall of a conductive container or the second electrode.

Field devices in the form of multisensors, which can operate both in a capacitive as well as also in a conductive operating mode, are known, for example, from DE102011004807A1, DE102013102055A1 and DE102014107927A1. Such multisensors are also suited for determining various media specific properties, such as the electrical conductivity, or dielectric properties of the medium, such as the dielectric constant, such as described, for example, in DE102013104781A1.

Problematic in the case of conductivity determination in process measurements technology are, among others, insulating layers, which can form in the region of the utilized electrodes. Other deposits on the electrode surfaces can bring about similar problems.

A reduction of the measurement error resulting from such layers can be achieved, for example, by the use of alternating signals, an increase of the frequency of the excitation signal and/or a reduction of a measured electrical current. Alternatively or supplementally, it is likewise known to produce the electrodes, at least partially, of graphite or platinum, or to use platinized electrodes.

Such measures, however, frequently limit the signal evaluation or make corresponding sensors relatively expensive.

Therefore, an object of the invention is to provide an as simple and exact opportunity as possible for determining and/or monitoring electrical conductivity.

The object is achieved by the method as defined in claim 1, as well as by the device as claimed in claim 8.

Regarding the method, the object of the invention is achieved by a method for determining and/or monitoring the conductivity of a medium by means of a measuring probe having at least one electrode, comprising method steps as follows:
supplying the measuring probe with an excitation signal,
receiving a received signal by the measuring probe,
ascertaining an ohmic part of the received signal, and
determining the conductivity of the medium based on the ohmic part of the received signal.

The method of the invention can be applied for all types of measuring probes suited for the capacitive and/or conductive measuring methods. The measuring probe can have one or more electrodes with different functions, such as, for example, a transmitting electrode, a receiving electrode, a ground electrode and/or a guard electrode. Also, the same electrode can have different functions.

According to the invention, the at least one electrode serves as transmitting electrode and a container wall or an optional second electrode is used as ground electrode. The second electrode can, at least at times, also serve as receiving electrode.

By ascertaining the ohmic part of the received signal, an influence of insulation- and/or other layers or deposits on the at least one electrode on the received signal can be eliminated or reduced. By the method of the invention, it is correspondingly possible to use a simple sensor, for example, having a stainless steel electrode or the like, and, indeed, without detriment to the accuracy of measurement as a result of deposits, especially insulating acting deposits, or insulating deposits, and/or polarization layers. Moreover, the range of applications can be significantly increased, since no special requirements need to be placed on the excitation signal, e.g. that it have a high frequency.

In an embodiment, the measuring probe is operated in a capacitive and/or in a conductive operating mode. The measuring probe includes, in such case, preferably at least two electrodes. Advantageously, other process variables of the medium can be ascertained in the two operating modes.

For example, involved, in such case, can also be a multisensor suitable both for capacitive as well as also for conductive process variable determination. In such case, the two operating modes can be performed alternately, at the same time or, in each case, at predeterminable points in time. In this connection, it is, for example, possible to form the excitation signal from two signal parts. In such case, a first signal part can be selected for application with the capacitive measuring mode and a second signal part for application with the conductive measuring mode. In this connection, reference is made to DE102014107927A1, which describes use of an excitation signal composed of two signal parts for implementing a capacitive and conductive multisensor.

It is, additionally, advantageous that, supplementally, a fill level or limit level of the medium in the containment be ascertained. Moreover, for example, also dielectric properties of the medium, for example, a dielectric constant, can be determined.

Another embodiment of the method of the invention includes that the received signal is recorded as a function of time. By logging as a function of time, evaluation of the received signal as regards conductivity can be significantly improved.

Examples of the excitation signal include a sine signal, a triangular signal, or a trapezoidal signal.

It is, however, especially advantageous, when a rectangular signal is used for the excitation signal. Use of a rectangular signal as excitation signal offers special advantages relative to determining the ohmic part of the received signal, such as will now be explained.

In using a rectangular signal as excitation signal, it is, additionally, advantageous that a first point in time is ascertained, at which the received signal has a step from a first value, especially a maximum value or minimum value, to a second value, and the difference between the first and second values is ascertained. The received signal as a function of time, thus, exhibits a jump, or step, which is detected, or ascertained. The height of the step can then be taken into consideration for the further signal evaluation.

Thus, it is, additionally, advantageous that, based on the difference between the first and second values, thus, based on the height of the step, the ohmic part of the received signal is ascertained. This ohmic part of the received signal is free of effects resulting from insulating layers or other deposits on the electrode surface.

The object of the invention is achieved, furthermore, by a device for determining and/or monitoring the conductivity of a medium in a containment with at least one measuring probe having at least one electrode, wherein the device is embodied to perform the method of the invention according to at least one of the described embodiments.

The device, especially the electronics, can be embodied especially analogously to the device described in DE102014107927A1.

It is to be noted here that the embodiments described in connection with the method of the invention can also be applied mutatis mutandis to the device of the invention.

The invention will now be described in greater detail based on the appended drawing, the figures of which show as follows:

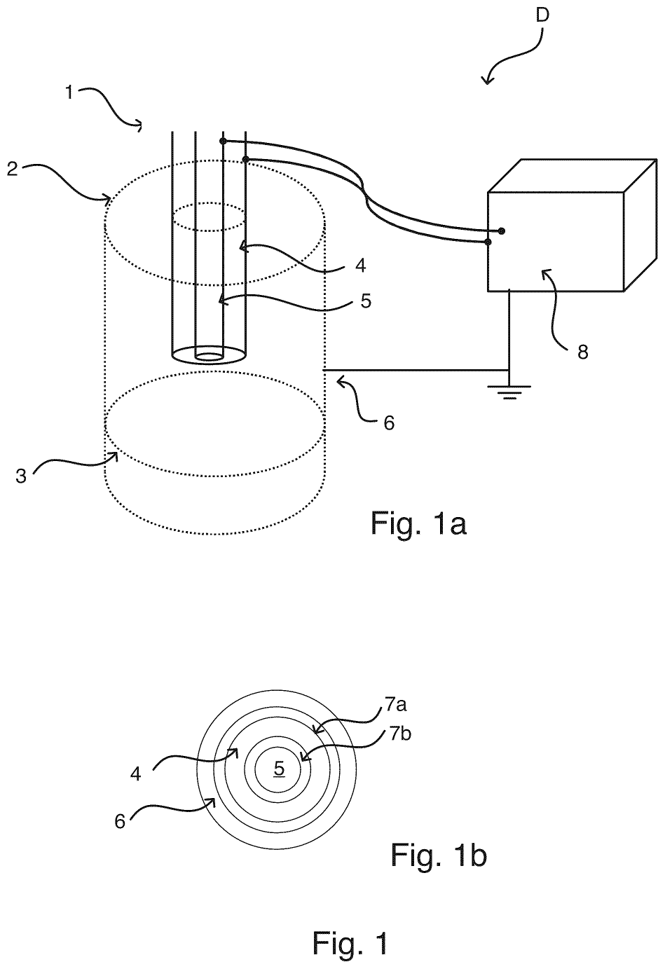

FIG. 1 by way of example, schematic views of a measuring probe for application with the method of the invention;

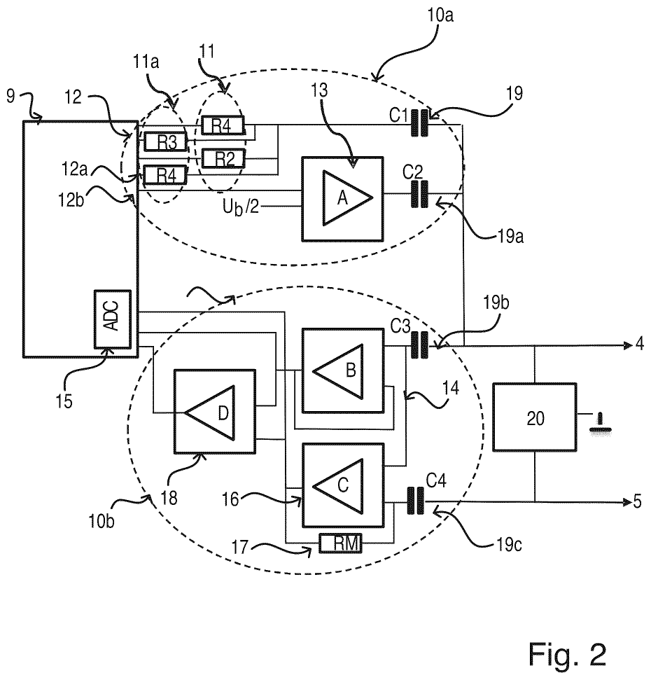

FIG. 2 a block circuit diagram of an electronics according to the state of the art;

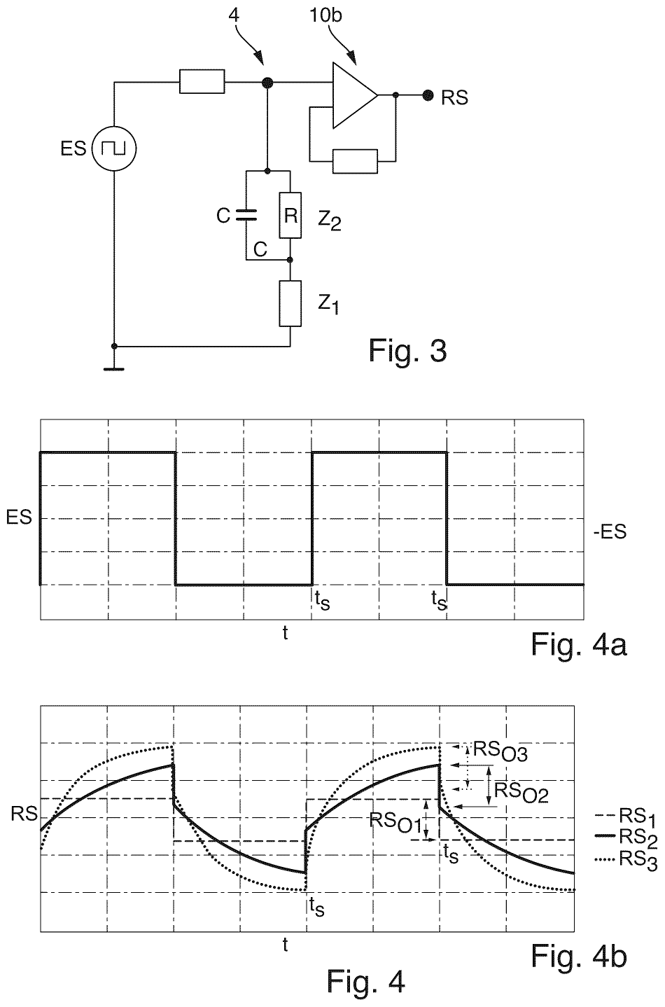

FIG. 3 a block circuit diagram for illustrating the method of the invention; and

FIG. 4(a) a rectangular excitation signal and (b) corresponding received signals, both as functions of time.

FIG. 1a shows, by way of example, an embodiment of a measuring probe 1 of a field device D, by means of which a process variable can be monitored in the capacitive or conductive measuring method. Measuring probe 1 is arranged in a container 2, which is filled, at least partially, with a medium 3. In such case, measuring probe 1 extends from the top of the container into such. It is understood, however, that the measuring probe 1 can in other embodiments also be so embodied such that it terminates with the wall of the container 3.

The measuring probe 1 itself is composed in the present example of two electrodes, a first electrode 4 and a second electrode 5, which serves for preventing the formation of accretion. The container wall further forms a ground electrode 6. Measuring probe 1 is additionally connected with an electronics 8, which is responsible for signal registration, evaluation and/or supply. Especially, the electronics 8 ascertains the process variable based on the received signals.

FIG. 1b shows a sectional view of a measuring probe 1 with three electrodes 4,5,6. The electrodes 4,5,6 are electrically isolated from one another by insulation 7a,7b and arranged concentrically. Such an embodiment of a measuring probe 1 is especially advantageous for a flushly mounted measuring probe 1 terminating with the container wall.

In the context of the invention, basically also the use of a measuring probe 1 having a single electrode 4 is possible. In such case, for example, the container wall can serve as a ground electrode.

FIG. 2 shows a block circuit diagram of an electronics 8, by means of which the measuring probe 1 can be operated both in the capacitive as well as also in the conductive operating mode. The invention is not limited to the shown electronics 8, but, rather, the shown embodiment is only one possible example of a suitable electronics 8. The electronics 8 of FIG. 2 corresponds to the electronics described in DE102014107927A1.

The shown electronics 8 includes a microcontroller 9 and is divided into a region 10a for producing the transmitted signal with different signal parts and into a region 10b for evaluating the received signals dependent on the signal parts.

Serving for producing a transmitted signal in the form of a rectangular signal for the conductive operating mode are two voltage dividers 11,11a, a low ohm dimensioned voltage divider (R1/R2) 11 for highly conductive media and a high ohm dimensioned voltage divider (R3/R4) 11a for slightly conductive media. The activation of these two voltage dividers 11,11a occurs via corresponding port-outputs 12,12a of the microcontroller 9. In the example shown here, a triangular voltage generated via the operational amplifier integrator 13 (block A) is selected via an additional port-output 12b of the microcontroller as transmitted signal for the capacitive operating mode.

The region 10b for evaluating the received signals dependent on the signal parts includes the blocks B to D, wherein all three comprise operational amplifiers. Furthermore, in order to minimize the influence of parasitic effects and accretion formation on the measuring probe 1, the guard technology of DE00102008043412A1 can be applied.

Block B 14 includes an amplifier, which places the reference signal, in this case, the guard voltage, on the analog-digital converter (ADC) 15 of the microcontroller 9. B 14 can likewise be used to shield at least one circuit board.

Also block C 16 comprises an amplifier, which is responsible for delivering the received signal to the ADC 15. In addition, a measuring resistor 17 is provided, with which the difference between the voltages on the transmitting electrode and the guard electrode is determinable.

For evaluating the received signal won from the capacitive measuring, supplementally, block D 18 is necessary, which comprises a difference amplifier, in order to subtract and amplify the two signals received from the transmitting- and guard electrodes. This is accomplished via the measuring resistor 17. The difference between the two received signals is directly proportional to the capacitance of the measuring probe 1. With such an electronics 8, a measurement resolution of a few femtofarads is possible.

Shown, moreover, in the block circuit diagram of FIG. 2 are four decoupling capacitors 19, 19a, 19b, 19c, which filter the direct voltage parts from the signals. Finally shown is the ESD protection circuit 20. Also an offset compensation can be performed.

The determining of the invention of the electrical conductivity will now be explained in greater detail based on the block circuit diagram of FIG. 3. A measuring probe 1 with an electrode 4 is supplied with excitation signal ES and the received signal RS is evaluated by means of the region 10b serving for evaluating the received signals.

The block circuit diagram of FIG. 3 further includes an equivalent circuit diagram of an impedance Z₁ of the electrode 4, shown simplified by a resistance, as well as an impedance Z₂ in the form of a parallel connection of a capacitor C and a resistor R for, in given cases present, insulating layers and/or other deposits in the region of the electrode 4. By means of the invention, the ohmic part of the received signal RS is determined, in order to determine the conductivity of the medium 3.

An example of determining the ohmic part of the received signal RS in case of a rectangular excitation signal ES is shown in FIG. 4. FIG. 4a shows the excitation signal ES as a function of time t and FIG. 4b shows three different received signals RS₁-RS₃ as a function of time t.

In the case, in which no insulating layers and/or deposits are present on the electrode 4, there results as received signal RS₁ likewise a rectangular signal and from the height of the steps RS_{O1} at the predeterminable points in time tₛ, in each case, starting from a maximum value or minimum value, the ohmic part RS_{O}, and, therewith, the conductivity of the medium 3, can be determined.

For the case of the slight presence of insulating layers and/or deposits on the electrode 4, there results a received signal RS₂, which has rising and falling edges and jumps, or steps, at the predeterminable points in time tₛ. The height of these jumps, or steps, RS_{O2} from a maximum-, or minimum value to, in each case, a second value at the predeterminable points in time tₛ results in the difference δ between the maximum-, or minimum, value and the second value and is again a measure for the ohmic part RS_{O} and therewith for the conductivity of the medium 3.

The height of the jumps, or steps, in the received signal RS, thus the difference δ, and therewith RS_{O}, increases with increasing insulating layer or deposit, such as illustrated by the received signal RS₃ and RS_{O3}, which concerns the case of significant insulating layers and/or deposits in the region of the electrode 4. Also the slope of the edges increases with increasing insulating layer and/or deposit.

An advantage of the invention is that the conductivity is ascertainable without influence of insulating layers and/or deposits present in the region of the electrode 4, or the electrodes 4-6. The conductivity results directly from the ohmic part of the received signal RS_{O}. In use of an excitation signal ES in the form of a rectangular signal, there results, additionally, an especially easy signal evaluation, which requires only the detection of jumps, or steps, in the received signal RS. The capacitive part of the received signal RS is negligible. Thus, the method of the invention can, in such case, be implemented in an especially easy manner.

### LIST OF REFERENCE CHARACTERS

1 measuring probe
2 containment
3 medium
4 first electrode
5 second electrode
6 third electrode
7 a,b insulation
8 electronics
9 microcontroller
10 a,b regions, respectively, for producing the transmitted signal and evaluating the received signals
11 11a voltage dividers
12 12a port outputs
13 block A, amplifier integrator
14 block B, amplifier
15 analog-digital converter (ADC)
16 block C, amplifier
17 measuring resistor
18 block D, difference amplifier
19 19a 19b 19c decoupling capacitors
20 ESD protection circuit
ES excitation signal
RS RS₁, RS₂, RS₃ received signals
Z Z₁, Z₂ impedances
RS_{O1}-RS_{O3} ohmic part of the received signal
tₛ predeterminable points in time
δ difference
D device

1-8. (canceled)

9. A method for determining and/or monitoring a conductivity of a medium using a measuring probe having at least one electrode, the method comprising:
supplying the measuring probe with an excitation signal;
receiving a received signal by the measuring probe;
ascertaining an ohmic part of the received signal; and
determining the conductivity of the medium based on the ohmic part of the received signal.

10. The method as claimed in claim 9,
wherein the measuring probe is operated in a capacitive and/or in a conductive operating mode.

11. The method as claimed in claim 9, further comprising:
ascertaining a fill level or a limit level.

12. The method as claimed in claim 9, further comprising:
recording the received signal as a function of time.

13. The method as claimed in claim 9,
wherein a rectangular signal is used for the excitation signal.

14. The method as claimed in claim 12, further comprising:
determining a first point in time at which the received signal has a step from a first value to a second value; and
determining a difference between the first and second values.

15. The method as claimed in claim 14,
wherein the ohmic part of the received signal is ascertained based on the difference.

16. A device for determining and/or monitoring a conductivity of a medium with a measuring probe having at least one electrode, wherein the device is embodied to:
supply the measuring probe with an excitation signal;
receive a received signal by the measuring probe;
ascertain an ohmic part of the received signal; and
determine the conductivity of the medium based on the ohmic part of the received signal.
